(19) United States
(12) Patent Application Publication
(10) Pub. No.: US 2025/0194313 A1
(43) Pub. Date: Jun. 12, 2025

(54) COMPOSITION, METHOD FOR CONNECTING A CARRIER AND AN ELECTRONIC COMPONENT, AND ELECTRONIC DEVICE

(71) Applicant: ams-OSRAM International GmbH, Regensburg (DE)

(72) Inventor: Thomas Schwarz, Regensburg (DE)

(21) Appl. No.: 18/846,166

(22) PCT Filed: Mar. 28, 2023
(86) PCT No.: PCT/EP2023/057960

§ 371 Date: Sep. 11, 2024

(30) Foreign Application Priority Data
Apr. 8, 2022 (DE) 102022108571.6

(51) Int. Cl. H10H 20/857; B23K 35/26; B23K 101/40; H10H 20/01; H10H 20/85

(52) U.S. Cl. CPC H10H 20/857; B23K 35/262; H10H 20/0364; H10H 20/8502; B23K 2101/40

(57) ABSTRACT

In an embodiment a composition includes a solder material, a photoresist and a flux, wherein the solder material is present in form of particles, wherein at least a part of the particles have a different diameter, and wherein the diameter differs by at least one power of ten.

### CROSS-REFERENCE TO RELATED APPLICATIONS

This patent application is a national phase filing under section 371 of PCT/EP2023/057960, filed Mar. 28, 2023, which claims the priority of German patent application 102022108571.6, filed Apr. 8, 2022, each of which is incorporated herein by reference in its entirety.

### TECHNICAL FIELD

A composition, a method for connecting a carrier and an electronic component, and an electronic device are disclosed.

### SUMMARY

Embodiments provide a composition that can be finely structured. Further embodiments provide an efficient and process-economical method for connecting a carrier and an electronic component. Yet other embodiments provide an electronic device, which has a firmly bonded connection, in particular a solder connection, between a carrier and an electronic component.

A composition is disclosed. In particular, the composition is suitable for use in a process for firmly bonding two elements, for example an electronic device. For example, the composition serves as a precursor for a solder connection.

According to at least one embodiment, the composition comprises a solder material. For example, the solder material is a soft solder. A solidus temperature of the solder material is preferably at most 350° C., particularly preferably at most 250° C., for example at most 150° C. In particular, the solidus temperature is the temperature at or below which the solder material is completely in a solid phase. For example, a solidus temperature of AuSn is 282° C., whereas a solidus temperature of Sn, SnAg, and SnAgCu is in the range between and including 220° C. and 230° C. Low-melting solders in particular have a solidus temperature of between and including 130° C. and 180° C.

In multiphase systems, the difference between the solidus temperature and a liquidus temperature, i.e. the temperature at which the solder material is completely in the liquid aggregate state, can be greater than 100° C. If a eutectic is used as the solder material, the solidus temperature can correspond to the liquidus temperature.

The solder material can be used for soldering. Presently, soldering is understood to mean, in particular, a firmly bonding of a surface of a first element and a surface of a second element. For example, in doing so, the solder material is converted from a solid aggregate state to a liquid aggregate state by thermal treatment. The liquid solder material then in particular forms an alloy with a material on the surface of the first element and with a material on the surface of the second element. During soldering, the liquidus temperature of the materials on the surfaces of the first element and the second element is preferably not reached. After the solder material has returned to the solid aggregate state, the surfaces of the first element and the second element are firmly bonded together with a solder connection comprising the solder material.

During soldering, the solder material is in particular completely transferred into a liquid aggregate state. This process is in contrast to sintering. During sintering, a material to be sintered is heated below its melting point, so that the material to be sintered is never completely in a liquid aggregate state.

According to at least one embodiment, the composition comprises a photoresist. In particular, the photoresist is a liquid resist, a dry resist or a resist film. For example, the photoresist is a positive resist or a negative resist. The photoresist is used in particular to attach the solder material to a surface, for example to a carrier.

In particular, the photoresist comprises a photoactive component. For example, a chemical reaction of the photoactive component is triggered by electromagnetic radiation. The chemical reaction can cause the photoresist to change solubility in a developing reagent. The solubility of the positive resist increases after treatment with electromagnetic radiation. The solubility of the negative resist decreases after treatment with electromagnetic radiation.

According to at least one embodiment, the composition comprises a solder material and a photoresist. In particular, the composition is a dispersion, for example a suspension or a mixture of solids, comprising the solder material and the resist. In the composition, the solder material and the photoresist are preferably mixed together and/or mechanically bonded.

The composition is advantageously suitable for applying solder material to areas of a surface that have an extension of at most 100 micrometers. This can be made possible by the photoresist selectively covering such small areas with the composition.

According to at least one embodiment, the composition comprises a solvent. Preferably, the photoresist in this embodiment is a liquid photoresist. The solvent is, for example, an alcohol, in particular with a boiling point of at least 200° C. For example, the solvent is selected from a group consisting of glycerol, decanol, and mixtures thereof.

In particular, the solvent reduces a viscosity of the composition. This enables, for example, easy processing and/or applying of the composition, for example by spraying. In addition, an amount of photoresist can be reduced due to the solvent in the composition. This makes it possible to provide a layer of the solder material and the photoresist with a low thickness after removing the solvent. Without the solvent, it may not be possible to easily process and/or apply the composition due to a small amount of photoresist.

According to at least one embodiment, the composition comprises a flux. In particular, the flux is an organic acid, preferably a carboxylic acid. For example, the flux comprises an organic acid selected from the group consisting of formic acid, acetic acid, fatty acids, rosin, and mixtures thereof.

The flux can reduce interfacial tension on the solder material. In particular, this improves the wetting of the surfaces of the first element and the second element by the solder material during soldering. Furthermore, oxides on the surfaces of the first element and/or the second element and/or the solder material can be removed by the flux.

According to at least one embodiment of the composition, a volume fraction of the photoresist relative to the total volume of the photoresist and the solder material is at most 50%, in particular at most 20%, for example at most 10%. Due to a low volume fraction of the photoresist, in particular a volume fraction of at most 10%, it is advantageously not necessary to remove the photoresist before soldering. This enables, for example, a shorter process flow during soldering.

According to at least one embodiment of the composition, the solder material is present in the form of particles. In particular, the particles are spherical or spheroidal. For example, the particles of the solder material are free of a flux.

According to at least one embodiment of the composition, the particles of the solder material have a diameter in the range of between and including 10 nanometers and 10 micrometers. In particular, the particles have a diameter in the range of between and including 10 nanometers and 4 micrometers.

Due to a small diameter of the particles, it is advantageously possible to apply the composition in areas having an extension of at most 100 micrometers. In other words, the composition described here offers in particular a resolution in the micrometer range. Furthermore, the composition can be applied in a low thickness due to the small diameter of the particles.

The composition can be structured—especially in a top view—in the form of dots, rectangles, or lines. Depending on the resolution of the photoresist, structure widths of a maximum of 20 micrometers, a maximum of 10 micrometers, or a maximum of 1 micrometer are possible. During application, quadrangle patterns, in particular square patterns, with the aforementioned structure widths are often produced for the connection of electrical contacts. The distance between the quadrangles, in particular the squares, is, for example, a maximum of 5 micrometers or a maximum of 20 micrometers.

In particular, the composition is applied to the entire surface of a substrate before exposure and development. Alternatively, the composition can be applied by screen printing only at the position where solder material is required. Since a structure size of screen printing is laterally significantly less precise and less accurate than a structure size of lithography, a larger area is printed than the area to be structured.

According to at least one embodiment of the composition, at least part of the particles comprise a different diameter. In particular, the diameter of the particles differs by at least a power of ten. This means, for example, that a part of the particles comprise a diameter in the range around 100 nanometers, whereas another part of the particles comprises a diameter in the range around 1 micrometer.

Due to the fact that at least a part of the particles comprise a different diameter, the solder material in the composition can be applied to the surface in a uniform distribution. In particular, there are only small areas on the surface that are not covered with the solder material. For example, spaces between larger particles of the solder material are filled with smaller particles of the solder material. Furthermore, it is not necessary to select particles with a specific diameter, which means that a cost-effective solder material can be used.

According to at least one embodiment of the composition, the diameters of the particles differ by at most 20%, in particular by at most 10%, for example by at most 5%. In other words, the particles have a similar diameter. Preferably, the particles have a diameter in the range of between and including 1 micrometer and 10 micrometers, in particular in the range of between and including 2 micrometers and 4 micrometers.

Advantageously, a smaller amount of photoresist is required to apply the particles with the similar diameter to the surface. This can be explained by the fact that it is sufficient to cover only part of an outer surface of the particles with the photoresist in order to achieve sufficient adhesion of the particles to the surface.

According to at least one embodiment of the composition, the solder material comprises or consists of Sn or a Sn alloy. In particular, the solder material comprises a material selected from a group formed by Sn, SnAg, SnAgCu, AuSn, SnBi, InSn, and mixtures thereof.

The solder material comprising Sn or the Sn alloy is characterized in particular by a high electrical conductivity and a high shear strength. In addition, Sn or Sn alloys have a low migration risk. This means that the components of the solder material do not migrate into other elements and/or layers of devices to be connected with the solder material.

Further, a method for connecting a carrier and an electronic component is disclosed. Preferably, the composition described herein is suitable and intended for use in the method described herein for bonding a carrier and an electronic component. Features and embodiments described in connection with the composition thus also apply to the method and vice versa.

According to at least one embodiment of the method, a carrier with a connection point is provided. In particular, the carrier is suitable for mechanically stabilizing an electronic component. Preferably, the connection point is configured to contact the electronic component mechanically and/or electrically.

According to at least one embodiment of the method, a composition is applied, in particular to the connection point and at least parts of the carrier. The composition comprises a solder material and a photoresist. By applying the composition, a photostructurable layer is formed on the carrier. The photostructurable layer comprises in particular the solder material and the photoresist.

According to at least one embodiment of the method, the photostructurable layer is photostructured. In particular, after photostructuring, the photostructurable layer remains on at least one area of the connection point of the carrier.

During photostructuring, for example, the photostructurable layer is exposed to electromagnetic radiation in such a way that a structure consisting of exposed areas and non-exposed areas is created in the photostructurable layer. The photostructurable layer can then be developed. Developing is understood here and in the following to mean in particular a process in which the photostructurable layer is removed in the exposed areas or the non-exposed areas. For example, developing is carried out using a developing reagent which comprises, in particular, water and/or an organic solvent.

If a positive resist is used in the method, exposure can increase the solubility of the photoresist in the developing reagent. When using the positive resist, the photostructurable layer in the exposed areas is in particular therefore removed. If a negative resist is used in the method, the solubility of the photoresist in the developing reagent can be reduced by the exposure. When the negative resist is used, the photostructurable layer is in particular therefore removed in the non-exposed areas.

According to at least one embodiment of the method, an electronic component is provided. The electronic component is, for example, an integrated circuit (IC) or an optoelectronic semiconductor chip.

According to at least one embodiment of the method, a solder connection is created between the electronic component and the connection point. At the same time, the solder connection is formed with a part of the solder material. In particular, the solder connection creates a mechanical and/or electrically conductive connection between the connection point and, in particular, the carrier and the electronic component. Creating the solder connection between the electronic component and the connection point can also be referred to as soldering the electronic component to the connection point.

The solder connection is created, for example, by heating the solder material, in particular to at least a liquidus temperature of the solder material, and then cooling it.

According to at least one embodiment, the method for connecting a carrier and an electronic component comprises the following steps:
providing a carrier with a connection point,
applying of a composition comprising a solder material and a photoresist, wherein a photostructurable layer is formed on the carrier,
photostructuring of the photostructurable layer,
providing an electronic component,
creating a solder connection between the electronic component and the connection point, wherein the solder connection is formed with a part of the solder material. Preferably, the steps are carried out in the order indicated.

Advantageously, a fine structuring of the composition with the solder material is possible with the method described herein. This makes it possible to mount electronic components with an expansion in the range of at most 200 micrometers on the carrier more efficiently and cost-effectively. It is therefore possible with the method to apply solder material with a high resolution, for example in the micrometer range, and thus create a solder connection between a comparatively small electronic component and a connection point.

In alternative methods, it is possible, for example, to use a photoresist layer as a mask for a solder paste. During this method, compared to the method described herein, more method steps are required to apply the solder paste with a correspondingly high resolution.

According to at least one embodiment of the method, photostructuring is carried out using electromagnetic radiation in the ultraviolet to blue wavelength range of the electromagnetic spectrum. The electromagnetic radiation is generated, for example, with the aid of a light-emitting diode (LED).

According to at least one embodiment of the method, the photostructuring is carried out by one of the following methods: proximity exposure, contact exposure, stepper, laser direct imaging (LDI), exposure through glass or metal masks.

During proximity exposure, a mask is positioned over the photostructurable layer at a distance in the micrometer range before exposure. During contact exposure, on the other hand, the mask can be in direct contact with the photostructurable layer. In particular, in this the stepper is a lithography system in which the photostructuring of the photostructurable layer is carried out. In particular, here neighboring areas are exposed one after the other. During laser direct imaging, a laser beam can be used for photostructuring the photostructurable layer. In particular, here only an electronic or virtual mask is required.

According to at least one embodiment of the method, the composition comprises a solvent. In this case, applying of the composition comprises in particular the following steps:
applying of the composition and
removing of the solvent so that the photostructurable layer is formed on the carrier.

Due to the solvent in the composition, it possible to apply the composition evenly and with a simple, efficient and cost-effective method.

According to at least one embodiment of the method, the composition is applied by one of the following methods: lamination, screen printing, stencil printing, spin coating, slot die coating, spray coating, dispensing. Lamination is used in particular for a photoresist that is formed as a resist film.

According to at least one embodiment of the method, after the photostructuring of the photostructurable layer, a tacky flux is applied to the photostructurable layer. The tacky flux comprises in particular an organic acid, as already described in connection with the flux in the composition, and an adhesive component, for example an organic polymer. Furthermore, the tacky flux may contain a solvent. This enables in particular a simple application of the tacky flux, for example by spraying.

In particular, the tacky flux improves the wetting of the connection point and the electronic component with the solder material. Furthermore, the tacky flux can serve as a catch layer when the electronic component is applied, in particular by laser-induced forward transfer (LIFT).

According to at least one embodiment of the method, the photoresist is removed before the solder connection is created. In particular, removing the photoresist is carried out by temperature treatment and/or treatment with a plasma, for example an oxygen plasma. When the oxygen plasma is used, in particular an oxide layer is produced on the solder material.

By removing the photoresist, residues of the photoresist in the solder connection can advantageously at least be reduced. In particular, this improves the electrical conductivity and shear strength of the solder connection.

According to at least one embodiment of the method, a part of the solder material is melted after the photostructuring and before creating the solder connection. In other words, the solder material is heated above its liquidus temperature. The part of the solder material that is melted is in particular the part of the solder material that remains on at least one area of the connection point after photostructuring. Preferably, the solder material is melted before applying the tacky flux.

Advantageously, the melting of the solder material can cause the photoresist to decompose. This results in particular in a solder connection that has little photoresist residue. Furthermore, the number of voids in the solder connection can be reduced by melting the solder material before providing and, in particular, applying the electronic component.

According to at least one embodiment of the method, the electronic component is applied to the photostructurable layer, in particular after photostructuring. Applying is, for example, carried out by laser-induced forward transfer (LIFT). In particular, the electronic component is applied after applying the tacky flux.

According to at least one embodiment of the method, the solder connection comprises a thickness in the range of between and including 0.5 micrometers and 5 micrometers, in particular in the range of between and including 1 micrometer and 2 micrometers. The method described herein can thus advantageously be used to produce a solder connection with a low thickness.

An electronic device is further disclosed. Preferably, the method for connecting a carrier and an electronic device described herein is suitable and provided for producing the electronic device. Features and embodiments described in connection with the method for connecting a carrier and an electronic component and the composition thus also apply to the electronic device and vice versa.

According to at least one embodiment, the electronic device comprises a carrier with a connection point. In particular, the carrier serves to mechanically stabilize the electronic device. Furthermore, electronic components on the carrier can be electrically conductively contacted via the connection point. Preferably, the carrier has an upper side and a lower side. The connection point is arranged on the upper side of the carrier, for example. Furthermore, the connection point can be flush with a remaining material of the carrier.

According to at least one embodiment, the electronic device comprises an electronic component. In particular, the electronic component is arranged on the upper side of the carrier. Preferably, the electronic component covers and/or protrudes above the connection point.

According to at least one embodiment, the electronic device comprises a solder connection with a solder material. In particular, the solder connection establishes a mechanical and electrical contact between the carrier and preferably the connection point and the electronic component.

According to at least one embodiment of the electronic device, the solder connection is arranged at least between the connection point and the electronic component. The solder connection can protrude laterally beyond the connection point. In particular, the solder connection is in direct contact with the connection point and the electronic component.

According to at least one embodiment of the electronic device, the carrier and the electronic component are connected using the method described above.

According to at least one embodiment, the electronic device comprises a carrier with a connection point, an electronic component and a solder connection with a solder material, wherein the solder connection is arranged at least between the connection point and the electronic component and wherein the carrier and the electronic component are connected by the method described above.

According to at least one embodiment of the electronic device, the electronic component is an optoelectronic semiconductor chip or an integrated circuit. In particular, the integrated circuit has a longest edge length in the range of between and including 10 micrometers and 200 micrometers. For example, the integrated circuit is based on silicon. The optoelectronic semiconductor chip is in particular a micro-LED. For example, the optoelectronic semiconductor chip has a longest edge length of between and including 10 micrometers and 100 micrometers. Preferably, the optoelectronic semiconductor chip has a square or rectangular shape in plan view, in particular with an aspect ratio of 1:1 up to and including 2:1.

According to at least one embodiment of the electronic device, the electronic component is a micro light emitting diode (LED).

Micro-LEDs can have a width, a length, a thickness and/or a diameter smaller than or equal to 100 micrometers, in particular smaller than or equal to 70 micrometers, for example smaller than or equal to 50 micrometers. In particular, micro-LEDs, for example rectangular micro-LEDs, have an edge length, in particular in plan view of the layers of the layer stack, of a luminous surface smaller than or equal to 70 micrometers, for example smaller than or equal to 50 micrometers. A micro-LED is, for example, a light-emitting diode in which a growth substrate is removed, so that a thickness of the micro-LED is, for example, in the range of between and including 1.5 micrometers and 10 micrometers.

For example, the micro-LED is provided on a wafer with detachable holding structures. The micro-LED can be detached from the wafer non-destructively.

According to at least one embodiment of the electronic device, the electronic component comprises at least one further connection point, in particular at least two further connection points. Preferably, the integrated circuit comprises more than two further connection points, particularly preferably at least six further connection points. For example, the further connection point of an integrated circuit has a size of about 5 micrometers×about 5 micrometers or about 10 micrometers×about 10 micrometers. Preferably, the optoelectronic semiconductor chip has two connection points.

According to at least one embodiment of the electronic device, the connection point of the carrier and the at least one further connection point are electrically conductively and mechanically connected to each other by the solder connection. In particular, the connection point and the at least one other connection point in the electronic component are directly opposite each other.

According to at least one embodiment of the electronic device, the at least one further connection point comprises Ag and/or Au. In particular, the at least one further connection point comprises a material selected from the following group: NiAu, NiAg, PdAu, PdAg, PtAu, and PtAg. The materials described before are in particular laminates of the various metals and not alloys. Preferably, the at least one further connection point comprises Ni in addition to Ag and/or Au. Ni is characterized in particular by a low solubility in the solder material, so that the at least one further connection point is not or only slightly dissolved in the solder material when creating the solder connection.

According to at least one embodiment of the electronic device, the connection point of the carrier comprises Cu, NiAu, NiPdAu, or TiPtAu. NiAu, NiPdAu, and TiPtAu are in particular not alloys but laminates of the corresponding metals.

According to at least one embodiment of the electronic device, the carrier comprises or consists of an element selected from the group consisting of a printed circuit board (PCB), a flexible printed circuit (FPC), metallized polyethylene terephthalate, metallized polyethylene naphthalate, a ceramic, a glass with thin film transistors (TFT), silicon and an integrated circuit (IC).

According to at least one embodiment of the electronic device, the solder connection comprises residues of a photoresist and/or decomposition products of a photoresist. An object in which the carrier and the electronic component have been joined by a method described herein is characterized in particular by this feature. Alternatively or additionally, the solder connection comprises voids, residues of a flux and/or residues of a tacky flux.

The voids, the residues of the photoresist, the decomposition products of the photoresist, the residues of the flux and the residues of the tacky flux can be detected, for example, by IR spectroscopy, X-ray photoelectron spectroscopy (XPS) or scanning electron microscopy (SEM) in a section through the solder connection. In particular, the residues of the photoresist, the flux and the tacky flux and the decomposition products of the photoresist are present in very low concentrations in the solder connection. However, these residues advantageously have little or no effect on the properties of the solder connection.

The residues of the photoresist, the flux, and the tacky flux are in particular parts of the photoresist, the flux and the tacky flux that remain in the solder connection after creating the solder connection. The decomposition products of the photoresist are formed, for example, when creating the solder connection, in particular when heating the solder material.

### BRIEF DESCRIPTION OF THE DRAWINGS

Further advantageous embodiments, configurations, and further developments of the composition, of the method for connecting a carrier and an electronic component, and of the electronic device result from the following exemplary embodiments shown in conjunction with the figures.

FIGS. 1A to 1H, 2A to 2G, 3A to 3H, 4A to 4H, 5A to 5H and 6A to 6H show schematic sectional views of stages of a method for connecting a carrier and an electronic component, each according to an exemplary embodiment; and

FIG. 7 shows a schematic sectional view of an electronic device according to an exemplary embodiment.

Elements that are identical, similar, or have the same effect are marked with the same reference signs in the figures. The figures and the proportions of the elements shown in the figures should not be considered as to be to scale. Rather, individual elements, in particular layer thicknesses, may be shown in exaggerated size for better visualization and/or understanding.

### DETAILED DESCRIPTION OF ILLUSTRATIVE EMBODIMENTS

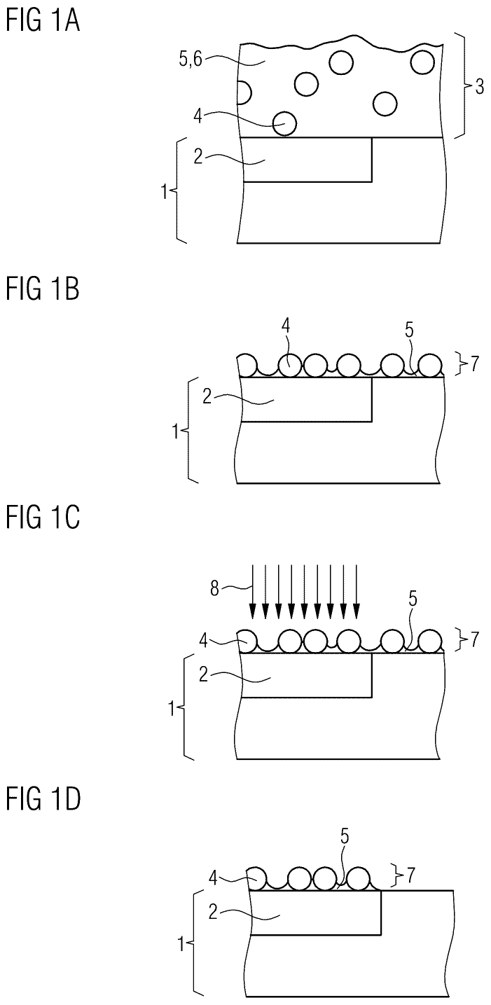

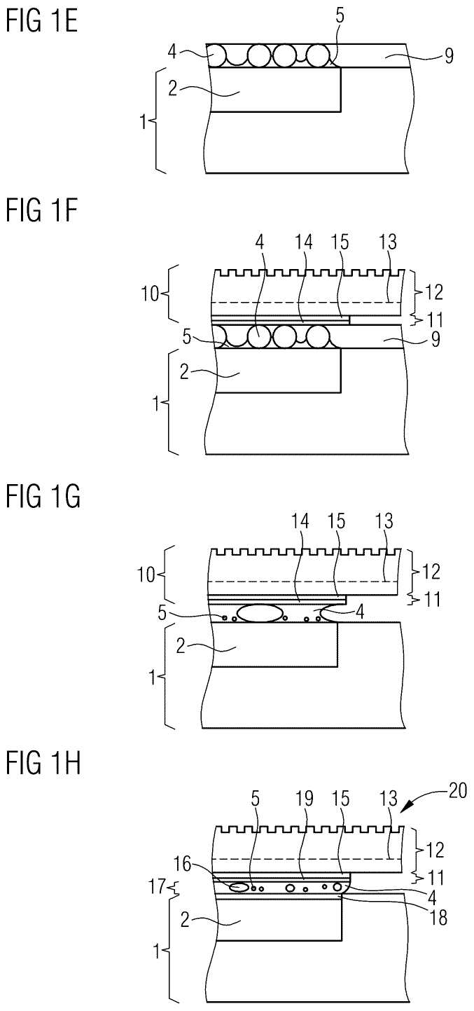

FIGS. 1A to 1H show stages of a method for connecting a carrier 1 and an electronic component 10 according to an exemplary embodiment. First, the carrier 1 with a connection point 2 is provided (FIG. 1A). Presently, the carrier 1 is a printed circuit board. The connection point 2 is flush with a remaining material of the carrier 1. The connection point 2 comprises or consists of Cu. A composition 3 is applied to the carrier 1 and its connection point 2 by screen printing or stencil printing. The composition 3 comprises a solder material 4, a photoresist 5 and a solvent 6.

The solder material 4 is in the form of particles and comprises Sn. A diameter of the particles differs from each other by at most 20%. The diameter of the particles is in the range of between and including 1 micrometer and 10 micrometers. The solvent 6 is glycerol. The photoresist 5 is a negative resist. A volume fraction of the photoresist 5 based on the total volume of the photoresist 5 and the solder material 4 is at most 50%, in particular at most 20%, preferably at most 10%.

As shown in FIG. 1B, the solvent 6 is removed. In this way, a photostructurable layer 7 is formed on the carrier 1 and the connection point 2. Presently, the photostructurable layer 7 comprises the solder material 4 and the photoresist 5. The photoresist 5 only partially encloses the solder material 4.

The photostructurable layer 7 is then photostructured. For this purpose, the

photostructurable layer 7 is exposed to electromagnetic radiation 8 in the ultraviolet wavelength range of the electromagnetic spectrum, as shown in FIG. 1C. This creates a structure of exposed areas and non-exposed areas in the photostructurable layer 7. The exposed areas at least partially cover the connection point 2. The exposure is carried out, for example, with proximity exposure, contact exposure, stepper, laser direct imaging or by exposure through glass or metal masks.

In a subsequent step, the photostructurable layer 7 is developed (FIG. 1D). In doing so, the photostructurable layer 7 is removed in the unexposed areas using a developing reagent. The photostructurable layer 7 remains at least on areas, preferably completely on the connection point 2. A part of the carrier 1 is free of the photostructurable layer 7 after photostructuring.

A tacky flux 9 is applied to the carrier 2, as shown in FIG. 1E. The tacky flux 9 covers the remaining photostructurable layer 7 at least partially, preferably completely. The tacky flux 9 fills gaps between the solder material 4.

An electronic component 10, presently an optoelectronic semiconductor chip, is provided and applied to the carrier 2 (FIG. 1F). The electronic component 10 comprises a further connection point 11 and an epitaxial semiconductor layer sequence 12 with an active zone 13. The active zone 13 is configured to generate and/or detect electromagnetic radiation. The further connection point 11 comprises an Au layer 14 and a Ni layer 15. In other words, the further connection point 11 has NiAu. The connection point 2 and the further connection point 11 are directly opposite each other. The photostructurable layer 7 and the tacky flux 9 are arranged between the connection point 2 and the further connection point 11. In particular, the further connection point 11 is in direct contact with the tacky flux 9.

A solder connection 17 comprising a part of the solder material 4 is then created. For this purpose, the solder material 4, which has remained on the carrier 1 and in particular the connection point 2 after the photostructuring, is heated to at least a liquidus temperature of the solder material 4. In doing so, the solder material 4 at least partially wets the connection point 2 and the other connection point 11 (FIG. 1G).

The solder material 4, which remained on the carrier 1 after the photostructuring, is cooled so that the solder connection 17 is formed (FIG. 1H). During cooling the solder material 4, it contracts. By creating the solder connection 17, a connecting layer 18 is formed on a surface of the connection point 2 facing the solder connection 17. The connecting layer 18 comprises an alloy of a part of the solder material 4 and at least a part of the material of the connection point 2. Presently, the connecting layer accordingly comprises a CuSn alloy. Starting from the Au layer 14, a further connecting layer 19 is formed by creating the solder connection 17. The further connecting layer 19 comprises a SnAuNi alloy.

The solder connection 17 of FIG. 1H comprises voids 16 as well as residues of the photoresist 5 and the tacky flux 9. In particular, the residues of the tacky flux 9 are arranged at a boundary of the voids 16. After creating the solder connection 17, an electronic device 20 is in particular produced.

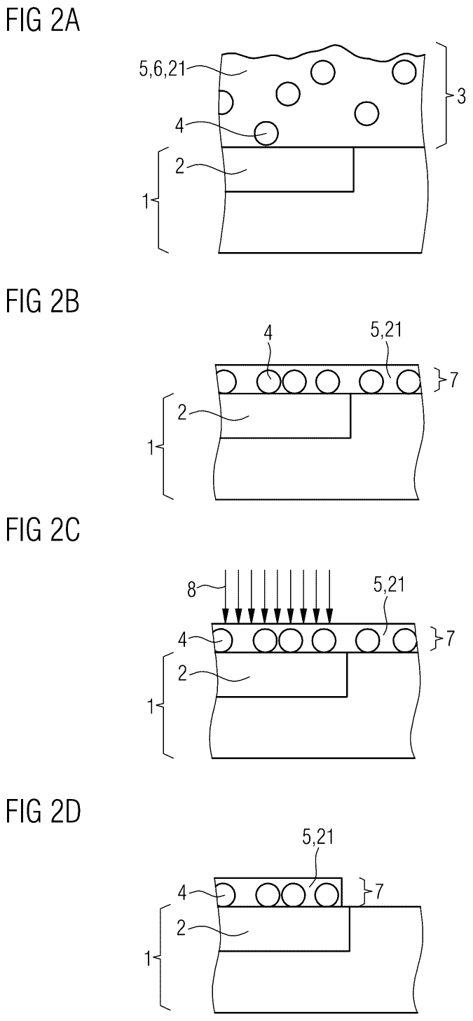

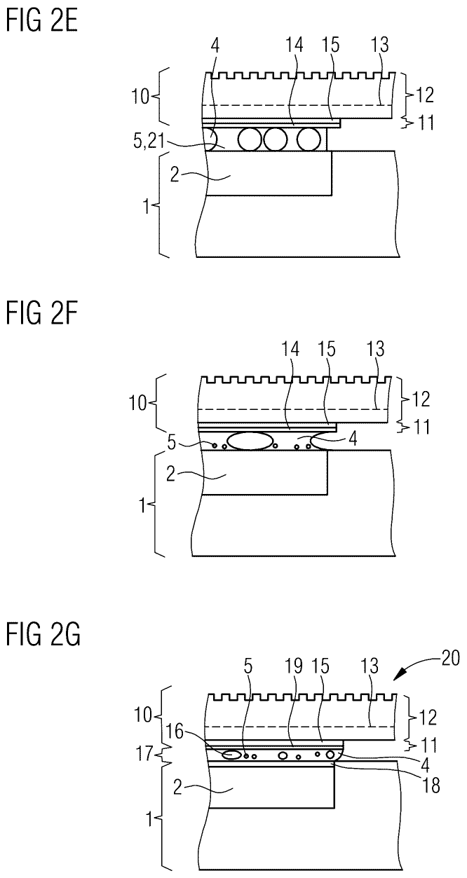

FIGS. 2A to 2G show stages of a method for connecting a carrier 1 and an electronic component 10 according to a further exemplary embodiment. In contrast to the previously described exemplary embodiment of the method, presently a composition 3 is applied to the carrier 1 which comprises a flux 21 in addition to the solder material 4, the photoresist 5 and the solvent 6 (FIG. 2A). The solder material 4, the photoresist 5, and the solvent 6 have already been described in detail in connection with FIG. 1A.

As already described in connection with FIG. 1B, the solvent 6 is removed so that a photostructurable layer 7 is formed (FIG. 2B). Presently, the photostructurable layer 7 comprises the solder material 4, the photoresist 5, and the flux 21. Subsequently, the photostructurable layer is photostructured by exposure to electromagnetic radiation 8 and development, as shown in FIGS. 2C and 2D.

As already described in connection with FIG. 1E, an electronic component 10 is applied (FIG. 2E). Presently, the further connection point 11 is in direct contact with the photostructurable layer 7. The photostructurable layer 7 is shrunk. Analogous to FIGS. 1G and 1H and their description, a solder connection 17 is formed between the electronic component, in particular the further connection point 11, and the connection point 2 of the carrier 1 (FIGS. 2F and 2G). The solder connection 17 comprises at least a part of the solder material 4, which was applied to the carrier 1 and the connection point 2 as part of the composition 3.

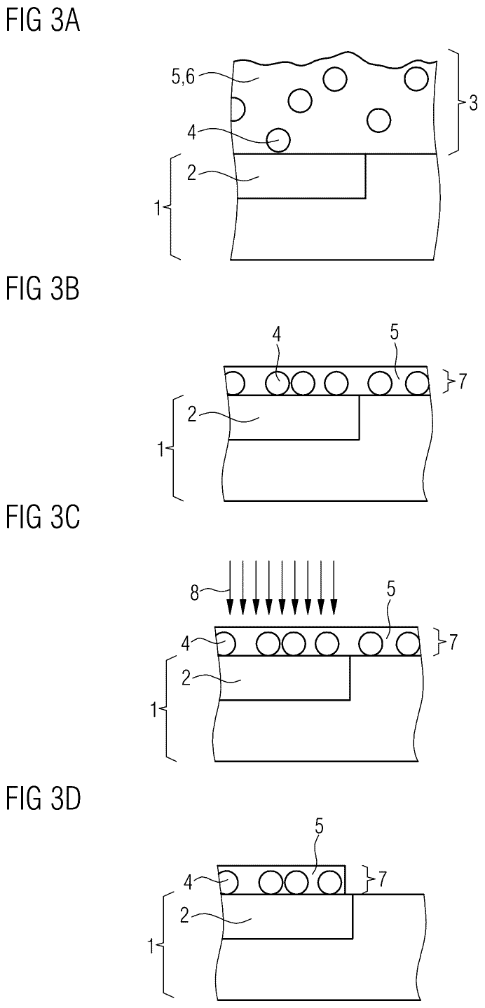

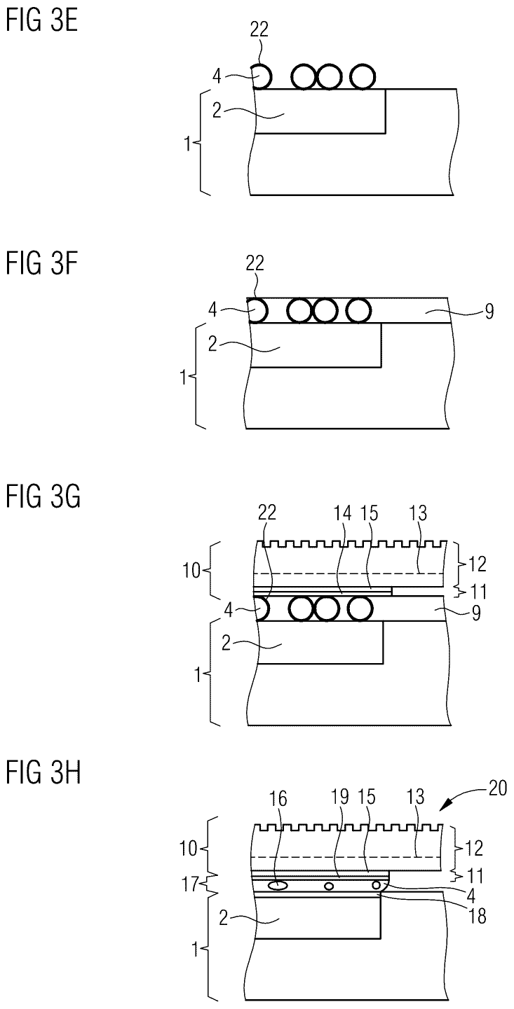

FIGS. 3A to 3H show stages of a method for connecting a carrier 1 and an electronic component 10 according to another exemplary embodiment. As already described in connection with FIGS. 1A to 1D, a carrier 1 with a connection point 2 is provided, a composition 3 comprising a solder material 4, a photoresist 5, and a solvent 6 is applied (FIG. 3A), the solvent 6 is removed (FIG. 3B) so that a photostructurable layer 7 is formed, and the photostructurable layer 7 is photostructured by exposure to electromagnetic radiation 8 and development (FIGS. 3C and 3D). In contrast to FIGS. 1B to 1D, the photoresist 5 completely encloses the solder material 4 in the photostructurable layer 7.

After photostructuring, the photoresist 5 is at least partially, preferably completely, removed (FIG. 3E). For example, the photoresist 5 is removed by treatment with an oxygen plasma. In doing so, an oxide layer 22 is formed around the solder material 4.

A tacky flux 9 is then applied, as shown in FIG. 3F. The tacky flux 9 covers the solder material 4 remaining on the carrier 1 after photostructuring at least partially, preferably completely.

As already described in connection with FIGS. 1F to 1H, an electronic component 10 is applied (FIG. 3G) and then a solder connection 17 is created between the further connection point 11 of the electronic component 10 and the connection point 2 of the carrier (FIG. 3H). Since the photoresist 5 was at least partially, preferably completely, removed before creating the solder connection 17, the solder connection 17 in particular has very little or no residue of the photoresist 5.

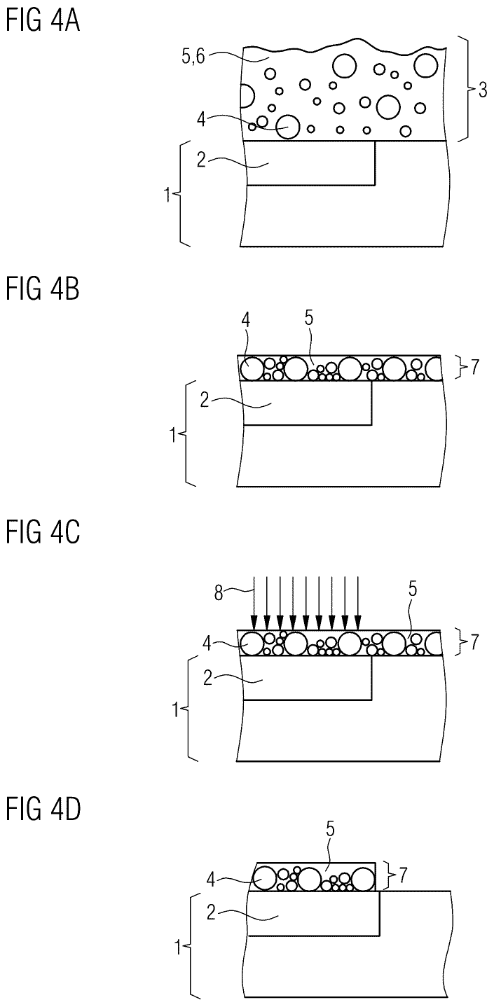

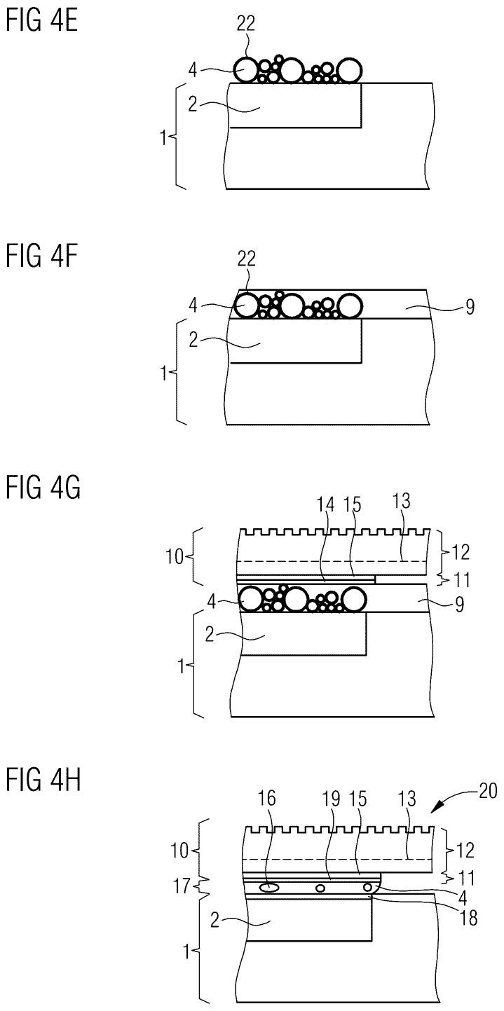

FIGS. 4A to 4H show stages of a method for connecting a carrier 1 and an electronic component 10 according to a further exemplary embodiment. As shown in FIG. 4A, a carrier 1 is first provided with a connection point 2. A composition 3 is applied. Presently, the composition 3 comprises a solder material 4, a photoresist 5, and a solvent 6. The solder material 4 is in the form of particles and comprises Sn or a Sn alloy. A diameter of a part of the particles differs by at least 20%. The diameter of the particles is in a range of between and including 10 nanometers and 10 micrometers. In particular, the diameter of a part of the particles differs by a power of ten. The photoresist 5 is presently a negative resist. The solvent 6 comprises decanol.

After applying of the composition 3, the solvent 6 is removed so that a photostructurable layer 7 is formed on an upper side of the carrier 1 and in particular on an upper side of the connection point 2 (FIG. 4B). In the photostructurable layer 7, the photoresist 5 encloses the solder material 6 at least partially, preferably completely.

The photostructurable layer 7 is then photostructured. This is carried out by exposing the photostructurable layer 7 to light in partial areas, as shown in FIG. 4C, and by removing a part of the photostructurable layer 7, as shown in FIG. 4D. The exposure is carried out with electromagnetic radiation 8 in the ultraviolet wavelength range of the electromagnetic spectrum. The photostructurable layer 7 is removed in the partial areas that were not exposed. The photostructurable layer 7 is removed using a developing reagent. The photostructurable layer 7 is removed in such a way that it remains at least partially, preferably completely, on the connection point 2.

After photostructuring, the photoresist 5 is removed in the remaining areas of the photostructurable layer 7 (FIG. 4E). In particular, when oxygen plasma is used, an oxide layer 22 is formed around the solder material 4, for example around the particles of the solder material 4.

A tacky flux 9 is applied, as shown in FIG. 4F. The tacky flux 9 covers at least a part of the solder material 4 and at least a part of the carrier 1 which is free of the photostructurable layer 7 after the photostructuring.

An electronic device 10 with a further connection point 11 is then provided and applied, as shown in FIG. 4G. The electronic device 10 has a structure that has already been described in detail in connection with FIG. 1F.

As shown in FIG. 4H, a solder connection 17 is then created between the connection point 2 and the electronic device 10, in particular its further connection point 11. The solder connection 17 is formed with a part of the solder material 4. In particular, the part of the solder material 4 is that part of the solder material 4 which remains on the connection point 2 after photostructuring, at least in an area. The solder connection 17 forms a firmly bonded connection between the connection point 2 and the electronic component 10.

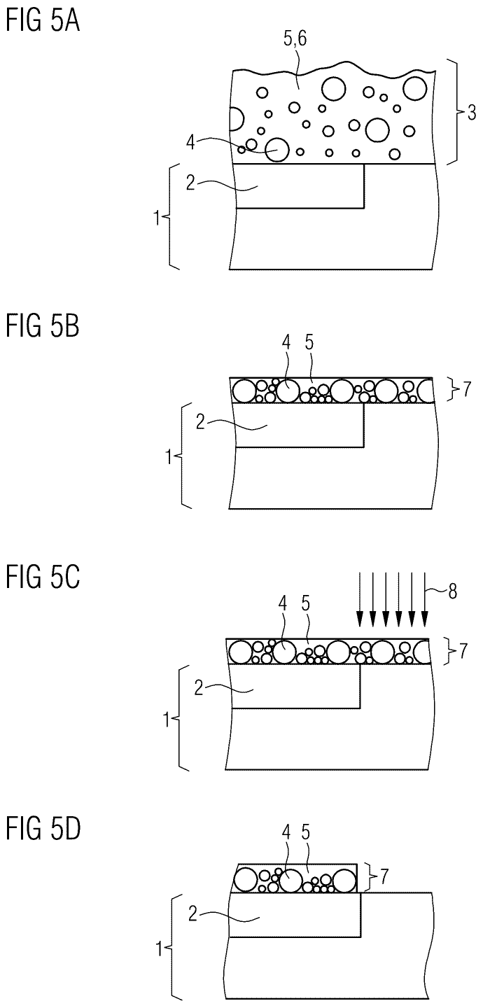

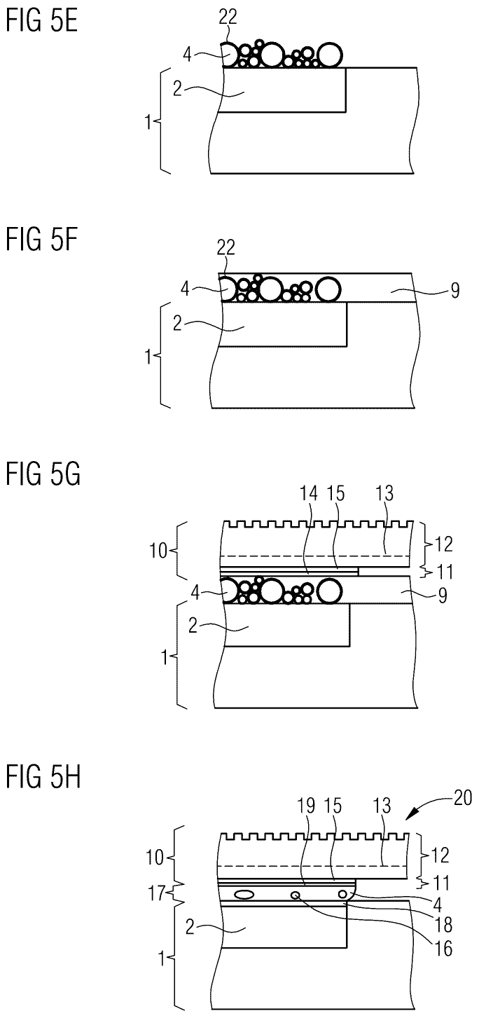

FIGS. 5A to 5H show stages of a method for connecting a carrier 1 and an electronic component 10 according to a further exemplary embodiment. The method is similar to the method described in connection with FIGS. 4A to 4H. However, the composition and the photostructurable layer 7 do not comprise a negative resist but a positive resist as photoresist 5.

After applying the composition 3 to the carrier 1 with the connection point 2 (FIG. 5A) and removing the solvent 6 (FIG. 5B) so that the photostructurable layer 7 is formed, the photostructurable layer 7 is exposed to electromagnetic radiation 8 (FIG. 5C). The exposure is carried out such that exposed and non-exposed areas are formed in the photostructurable layer 7. In particular, the unexposed areas at least partially cover the connection point 2.

To complete the photostructuring process, the photostructurable layer 7, and in particular the photoresist 5, is developed using a developing reagent. The photostructurable layer 7 is removed in the exposed areas during development. In doing so, only a part of the photostructurable layer 7 remains on the carrier 2. The remaining part of the photostructurable layer 7 at least partially covers the connection point 2 and comprises a part of the solder material 4.

Analogous to FIGS. 4E to 4H, the method for connecting a carrier 1 and an electronic component 10 is completed, as shown in FIGS. 5E to 5H.

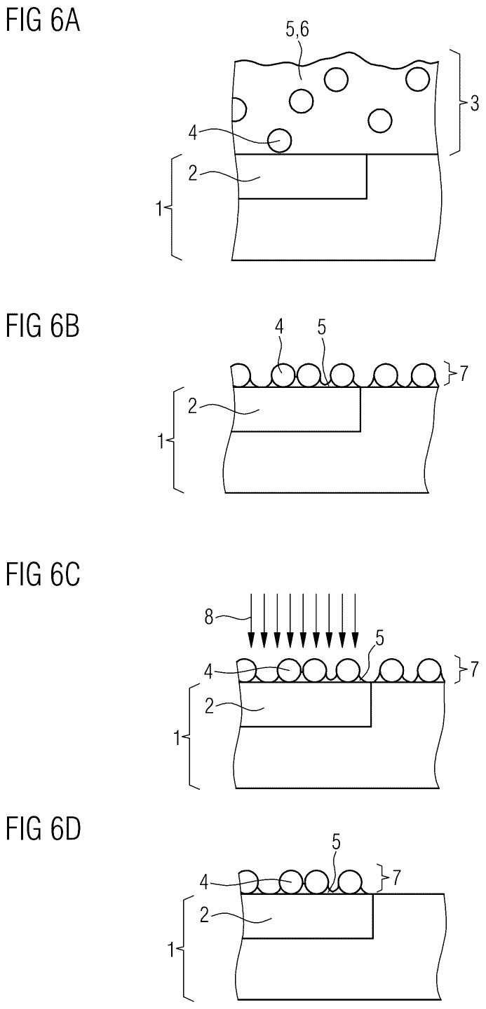

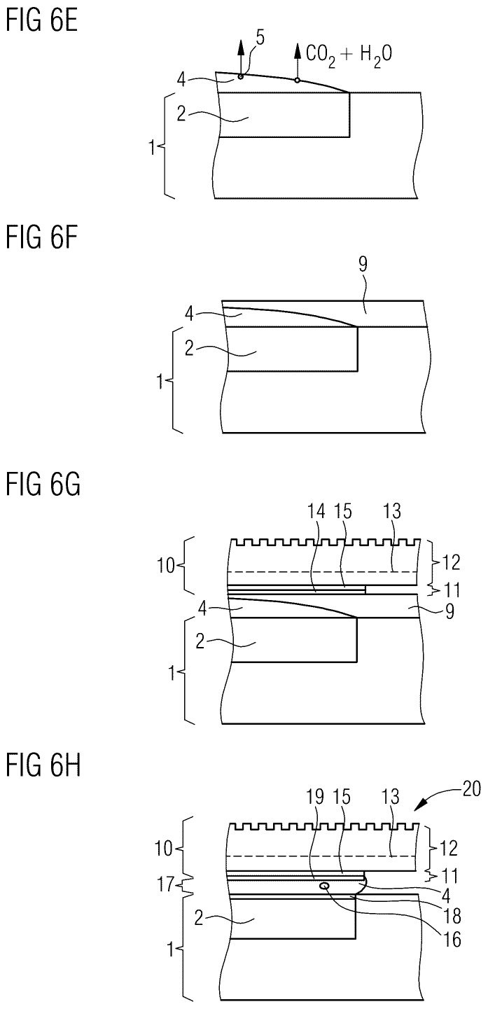

FIGS. 6A to 6H show stages of a method for connecting a carrier 1 and an electronic component 10 according to a further exemplary embodiment.

As already described in connection with FIGS. 1A to 1D, a carrier 1 having a connection point 2 is provided as shown in FIGS. 6A to 6D. A composition 3 comprising a solder material 4, a photoresist 5, and a solvent 6 is applied thereto. The solvent 6 is removed so that a photostructurable layer 7 is formed. The photostructurable layer 7 is then photostructured by exposure and development. The photostructuring is carried out in such a way that a part of the photostructurable layer 7 remains on the carrier 1. The part of the photostructurable layer at least partially covers the connection point 2.

After photostructuring, the part of the solder material 4 that remained on the carrier 1 and in particular the connection point 2 is melted, for example by heating (FIG. 6E). Melting the solder material 4, in particular by the heating, causes the photoresist 5 to decompose, for example into carbon dioxide (CO₂) and water (H₂O). The photoresist 5 is therefore at least partially removed by the melting process.

As shown in FIG. 6F, a tacky flux 9 is applied after melting the solder material 4. The tacky flux 9 covers the solder material 4, which remained on the carrier 1 and in particular the connection point 2 after the photostructuring, at least partially, preferably completely. The tacky flux 9 also covers at least parts of a surface of the carrier 1 that is not formed by the connection point 2.

An electronic component 10 is then provided and applied, as shown in FIG. 6G. The structure of the electronic component has already been described in detail in connection with FIG. 1F.

As shown in FIG. 6H, a solder connection 17 is then created between the electronic component 10, in particular its further connection point 11, and the connection point 2. The solder connection 17 is formed with the part of the solder material 4 that remained on the carrier 1 after the photostructuring of the photostructurable layer 7. The solder connection 17 is used to create a firmly bonded connection between the carrier 1 and the electronic component 10. Presently, the solder connection 17 has only a few voids 16 and preferably no residues and/or decomposition product of the photoresist 5. The further details for creating the solder connection have already been described in connection with FIGS. 1G and 1H.

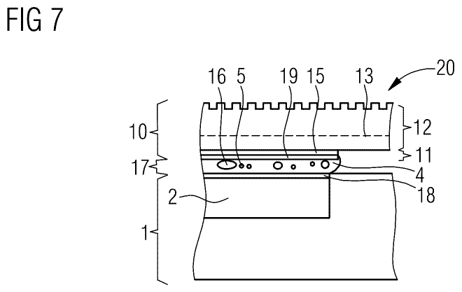

FIG. 7 shows an exemplary embodiment of an electronic device 20. Presently, the electronic device 20 comprises a carrier 1 with a connection point 2. The carrier 1 and the connection point 2 are flush with each other. In particular, the connection point 2 is embedded in the carrier 1. Presently, the carrier 1 is a flexible printed circuit board. The connection point 2 comprises Cu. The connection point has a connecting layer 18 comprising a CuSn alloy.

An electronic component 10 is arranged on the carrier 1. Presently, the electronic component 10 is an optoelectronic semiconductor chip with a semiconductor layer sequence 12 and a further connection point 11. The semiconductor layer sequence 12 has an active zone 13, which is designed to generate or detect electromagnetic radiation. The further connection point 11 has a Ni layer 15 and a further connecting layer 19. The further connecting layer 19 comprises a SnAuNi alloy. The connection point 2 and the further connection point 11 are directly opposite each other and are connected to each other by a solder connection 17. The further connection point 11 and the solder connection 17 protrude laterally beyond the connection point 2.

The solder connection 17 comprises a solder material 4, voids 16, and residues of a photoresist 5. Furthermore, the solder connection 17 may additionally comprise decomposition products of the photoresist 5 and/or residues of a flux 21 and/or residues of a tacky flux 9. The solder connection 17 is in direct contact with the connecting layer 18 and the further connecting layer 19. Presently, the solder material 4 comprises Sn or a Sn alloy, for example SnAg, SnAgCu, AuSn, SnBi or InSn. The solder connection 17 is used presently for the mechanical and electrical conductive connection of the carrier 1 and the electronic component 10.

The features and exemplary embodiments described in connection with the figures may be combined with one another in accordance with further exemplary embodiments, even if not all combinations are explicitly described. Furthermore, the exemplary embodiments described in connection with the figures may alternatively or additionally have further features as described in the general part.

The invention is not limited to the exemplary embodiments by the description thereof. Rather, the invention comprises any new feature as well as any combination of features, which includes in particular any combination of features in the patent claims, even if this feature or combination itself is not explicitly stated in the patent claims or exemplary embodiments.

1.-18. (canceled)

19. A composition comprising:
a solder material;
a photoresist; and
a flux,
wherein the solder material is present in form of particles,
wherein at least a part of the particles have a different diameter, and
wherein the diameter differs by at least one power of ten.

20. The composition according to claim 19, wherein the composition comprises a solvent.

21. The composition according to claim 19, wherein a volume fraction of the photoresist relative to a total volume of the photoresist and the solder material is at most 50%.

22. The composition according to claim 19, wherein the particles have a diameter in a range of between and including 10 nanometers and 10 micrometers.

23. The composition according to claim 19, wherein the solder material comprises Sn or a Sn alloy.

24. A method for connecting a carrier and an electronic component, the method comprising:
providing the carrier with a connection point;
applying a composition comprising a solder material and a photoresist, wherein a photostructurable layer is formed on the carrier;
photostructuring the photostructurable layer;
providing the electronic component;
creating a solder connection between the electronic component and the connection point, wherein the solder connection is formed with a part of the solder material;
after photostructuring the photostructurable layer, applying a tacky flux to the photostructurable layer; and
removing the photoresist before creating the solder connection.

25. The method according to claim 24, wherein photostructuring comprises using one of the following methods: proximity exposure, contact exposure, stepper, laser direct imaging, or exposure through glass or metal masks.

26. The method according to claim 24,
wherein the composition comprises a solvent, and
wherein applying the composition comprises the following steps:
applying the composition, and
removing the solvent so that the photostructurable layer is formed on the carrier.

27. The method according to claim 24, wherein the composition is applied by one of the following methods: laminating, screen printing, stencil printing, spin coating, slot die coating, spray coating, or dispensing.

28. The method according to claim 24, wherein a part of the solder material is melted after photostructuring and before creating the solder connection.

29. An electronic device comprising:
the carrier with the connection point;
the electronic component; and
the solder connection with the solder material,
wherein the solder connection is arranged at least between the connection point and the electronic component,
wherein the carrier and the electronic component are connected by the method according to claim 24.

30. The electronic device according to claim 29, wherein the electronic component is an optoelectronic semiconductor chip.

31. The electronic device according to claim 30, wherein the optoelectronic semiconductor chip is a micro-LED.

32. The electronic device according to claim 29,
wherein the electronic component has at least one further connection point,
wherein the connection point of the carrier and the at least one further connection point are electrically conductively and mechanically connected to one another by the solder connection, and
wherein the at least one further connection point comprises Ag and/or Au.

33. The electronic device according to claim 29, wherein the connection point of the carrier comprises Cu, NiAu, NiPdAu, or TiPtAu.

34. The electronic device according to claim 29, wherein the carrier comprises an element from the following group: a printed circuit board, a flexible printed circuit, a metallized polyethylene terephthalate, a metallized polyethylene naphthalate, ceramic, glass with thin film transistors, silicon, or an integrated circuit.

35. The electronic device according to claim 29, wherein the solder connection comprises residues of a photoresist and/or decomposition products of the photoresist.
